(19) United States
(12) Patent Application Publication
(10) Pub. No.: US 2013/0140592 A1
(43) Pub. Date: Jun. 6, 2013

(54) LIGHT EMITTING DIODE WITH IMPROVED LIGHT EXTRACTION EFFICIENCY AND METHODS OF MANUFACTURING SAME

(71) Applicants: Yea-Chen Lee, Zhubei City (TW); Jung-Tang Chu, Zhunan Township (TW); Ching-Hua Chiu, Hsinchu City (TW); Hung-Wen Huang, Hsinchu City (TW)

(72) Inventors: Yea-Chen Lee, Zhubei City (TW); Jung-Tang Chu, Zhunan Township (TW); Ching-Hua Chiu, Hsinchu City (TW); Hung-Wen Huang, Hsinchu City (TW)

(73) Assignee: TAIWAN SEMICONDUCTOR MANUFACTURING COMPANY, LTD., Hsin-Chu (TW)

(21) Appl. No.: 13/308,784

(22) Filed: Dec. 1, 2011

(51) Int. Cl. H01L 33/22; H01L 33/36

(52) U.S. Cl. 257/98; 438/29; 257/E33.074; 257/E33.062

(57) ABSTRACT

A light emitting diode structure and methods of manufacturing the same are disclosed. In an example, a light emitting diode structure includes a crystalline substrate having a thickness that is greater than or equal to about 250 μm, wherein the crystalline substrate has a first roughened surface and a second roughened surface, the second roughened surface being opposite the first roughened surface; a plurality of epitaxy layers disposed over the first roughened surface, the plurality of epitaxy layers being configured as a light emitting diode; and another substrate bonded to the crystalline substrate such that the plurality of epitaxy layers are disposed between the another substrate and the first roughened surface of the crystalline substrate.

### BACKGROUND

A gallium nitride (GaN) based light emitting diode (LED) is typically grown on a sapphire substrate. Light extraction efficiency of the GaN-based LED is directly affected by various attributes of the sapphire substrate. For example, a thickness of the sapphire substrate, roughness characteristics of the sapphire substrate, and packaging methods used for the GaN-based LED/sapphire substrate all affect the light extraction efficiency of the GaN-based LED. Flip-chip technology has been implemented in GaN-based LEDs, where the GaN-based LED disposed on the sapphire substrate is assembled face down on another substrate (a sub-mount or supporting substrate), such that light comes from a backside of the LED through the sapphire substrate (which essentially acts as a “window layer”). Though flip-chip technology has provided desirable thermal conductivity and improved external quantum efficiency (EQE), challenges still exist in optimizing light extraction efficiency of the GaN-based LED, particularly related to limiting attributes of the sapphire substrate. Accordingly, although existing methods and structures for GaN-based LEDs have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of a method for manufacturing a light emitting diode (LED) structure according to various aspects of the present disclosure;

FIGS. 2-8 are diagrammatic cross-sectional views of a LED structure, in portion or entirety, at various fabrication stages according to the method of FIG. 1;

FIGS. 9-15 are diagrammatic cross-sectional views of another LED structure, in portion or entirety, at various fabrication stages according to the method of FIG. 1; and

FIGS. 16-21 are diagrammatic cross-sectional views of yet another LED structure, in portion or entirety, at various fabrication stages according to the method of FIG. 1.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

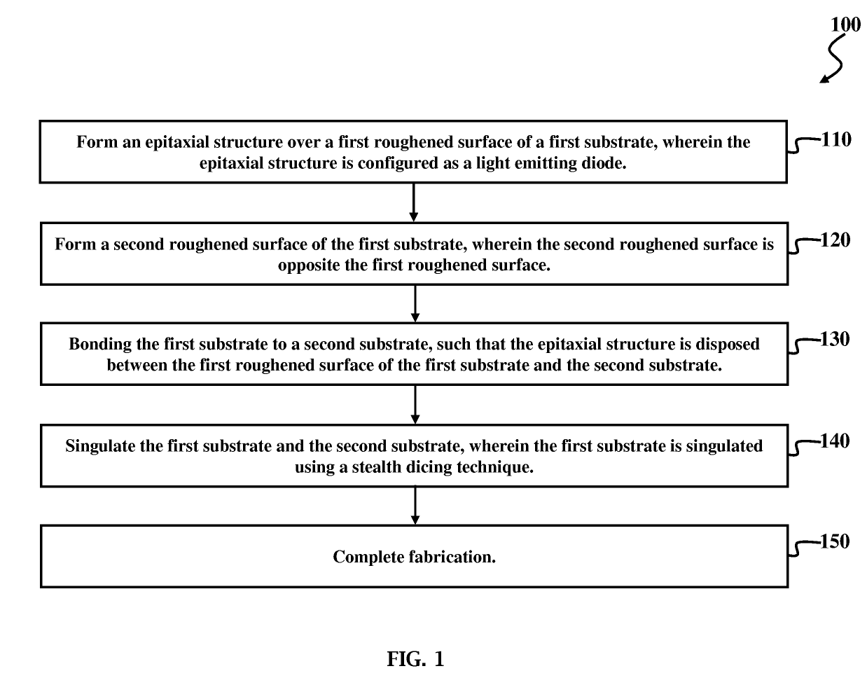

FIG. 1 is a flow chart of a method 100 for fabricating a light emitting diode (LED) structure according to various aspects of the present disclosure. The method 100 begins at block 110 where an epitaxial structure is formed over a first roughened surface of a first substrate. The epitaxial structure is configured as a light emitting diode. In an example, the first surface of the substrate is a roughened surface. In an example, the first substrate is a sapphire substrate. At block 120, a second surface of the substrate is roughened, thereby forming a second roughened surface of the first substrate. The second surface (and therefore the second roughened surface) is opposite the first roughened surface. In an example, the second surface is roughened by a dry etching process that uses a patterned metal layer as an etching mask. In another example, the second surface is roughened by a wet etching process that uses a patterned hard mask layer as an etching mask. In yet another example, the second surface is roughened by a lapping process that uses a nano-particle slurry. The roughened second surface includes nano-sized dips that enhance light extraction efficiency. At block 130, the first substrate is bonded to a second substrate, such that the epitaxial structure is disposed between the first roughed surface of the first substrate and the second substrate. In an example, a flip-chip process is used to bond the first substrate to the second substrate. The second substrate may be a baseboard. At block 140, the first substrate and the second substrate are singulated, wherein a stealth dicing technique is used to singulate the first substrate. A stealth dicing technique may also be used to singulate the second substrate. The singulated first substrate and second substrate may provide one or more LED dies. The method 100 may continue to block 150 where fabrication of the LED structure is completed. Additional steps can be provided before, during, and after the method 100, and some of the steps described can be replaced or eliminated for additional embodiments of the method. The discussion that follows illustrates various embodiments of an LED structure that can be fabricated according to the method 100 of FIG. 1.

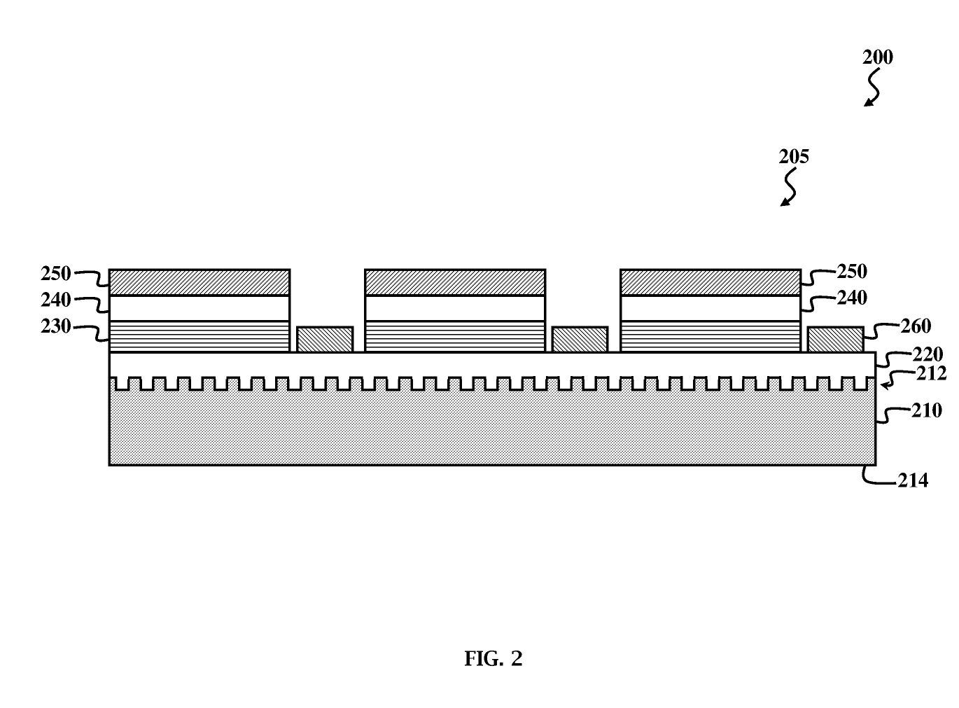

FIGS. 2-8 are various diagrammatic cross-sectional views of an embodiment of an LED structure 200, in portion or entirety, during various fabrication stages according to the method 100 of FIG. 1. FIGS. 2-8 have been simplified for the sake of clarity to better understand the inventive concepts of the present disclosure. Additional features can be added in the LED structure 200, and some of the features described below can be replaced or eliminated for additional embodiments of the LED structure 200.

Referring to FIG. 2, the LED structure 200 includes a LED wafer 205 that includes a substrate 210. In the depicted embodiment, the substrate 210 is a crystalline substrate, specifically a sapphire substrate. Alternatively, the substrate 210 includes silicon carbide (SiC), silicon, gallium nitride (GaN), other substrate material suitable for LED applications, or combinations thereof. The substrate 210 has a surface 212 (also referred to as a top surface of the substrate 210) and a surface 214 (also referred to as a bottom surface of the substrate 210) that is opposite the surface 212. The substrate 210 has a thickness that is measured between the surface 212 and the surface 214. In an example, the thickness of the substrate 210 is greater than or equal to about 250 μm. In another example, the thickness of the substrate 210 is about 250 μm to about 600 μm. In FIG. 2, the surface 212 is patterned or roughened, and the surface 214 is substantially planar. The surface 212 may therefore be referred to as a patterned surface or a roughened surface. The roughened surface 212 can enhance external quantum efficiency, internal quantum efficiency, or both of the LED structure 200. In the depicted embodiment, the roughened surface 212 has a periodic structure. Alternatively, the roughened surface 212 may have a non-periodic structure.

The LED wafer 205 includes various material layers disposed over the substrate 210, particularly over the roughened surface 212 of the substrate 210. For example, an epitaxial structure that includes various epitaxy layers 220, 230, and 240 is formed over the roughened surface 212. The epitaxy layers 220, 230, and 240 are designed to form one or more LEDs. In an example, the epitaxy layers include an n-typed doped semiconductor layer and a p-type doped semiconductor layer configured to emit radiation. In an example, the epitaxy layers include a single quantum well (SQW) structure disposed between the n-type doped semiconductor layer and the p-type doped semiconductor layer. The SQW structure includes two different semiconductor materials and can be used to tune the wavelength of the LED. Alternatively, a multiple quantum well (MQW) structure is interposed between the n-type doped semiconductor layer and the p-type doped semiconductor layer. The MQW structure includes a plurality of SQWs in a stack. The MQW structure preserves advantages of the SQW structure and has a larger volume of active region, allowing higher lighting power. In the depicted embodiment, the epitaxy layers 220, 230, and 240 include GaN based semiconductor materials configured to form GaN-based LEDs that emit blue light, ultraviolet (UV) light, or both. For example, the epitaxy layer 220 is an n-type doped GaN layer (n-GaN layer) disposed over the substrate 210, the epitaxy layer 230 is a MQW structure disposed over the n-GaN layer, and the epitaxy layer 240 is a p-type doped GaN (p-GaN) layer disposed over the MQW structure.

The epitaxy layer 220 (n-GaN layer) is epitaxially grown over the roughened surface 212 of the substrate 210. The n-GaN layer includes a gallium nitride layer doped with an n-type dopant, such as silicon or oxygen. In an example, a buffer layer, such as an undoped GaN layer or an aluminum nitride (AlN) layer, may be disposed between the epitaxy layer 220 (n-GaN layer) and the patterned surface 212 of the substrate 210. The buffer layer may be epitaxially grown over the patterned surface 212 of the substrate 210 before the n-GaN layer 220.

The epitaxy layer 230 (MQW structure) is formed over the epitaxy layer 220 (n-GaN layer) by various epitaxy growth processes. The MQW structure includes a plurality of pairs of semiconductor films, such as from about 5 pairs to about 15 pairs of semiconductor films. In an example, each pair of semiconductor films includes an indium gallium nitride (InGaN) film and a gallium nitride (GaN) film (forming InGaN/GaN pairs). The InGaN/GaN films can be doped with an n-type dopant. In another example, each pair of semiconductor films includes an aluminum gallium nitride (AlGaN) film and a gallium nitride film (forming AlGaN/GaN pairs). The AlGaN/GaN films can doped with an n-type dopant.

The epitaxy layer 240 (p-GaN layer) is epitaxially grown over the epitaxy layer 230 (MQW structure). The p-GaN layer includes a gallium nitride layer doped with a p-type dopant, such as magnesium, calcium, zinc beryllium, carbon, or combinations thereof.

The various epitaxy layers 220, 230, and 240 can be epitaxy grown by a suitable technique, such as metal organic chemical vapor deposition (MOCVD) or metal organic vapor phase epitaxy (MOVPE). In an example, the n-GaN layer (epitaxy layer 220), the MQW structure (epitaxy layer 230), and the p-GaN layer (epitaxy layer 240) can be epitaxy grown using gallium-containing precursor and nitrogen-containing precursor. The gallium-containing precursor includes trimethylgallium (TMG), triethylgallium (TEG), or other suitable chemical. The nitrogen-containing precursor includes ammonia (NH₃), tertiarybutylamine (TBAm), phenyl hydrazine, or other suitable chemical. In another example, where the MQW structure (epitaxy layer 230) includes AlGaN films, the AlGaN films can be epitaxy grown by MOVPE using aluminum-containing precursor, gallium-containing precursor, and nitrogen-containing precursor. The aluminum-containing precursor includes trimethylaluminum (TMA), triethylamine (TEA), or other suitable chemical; the gallium-containing precursor includes TMG, TEG, or other suitable chemical; and the nitrogen-containing precursor includes ammonia, TBAm, phenyl hydrazine, or other suitable chemical. Alternatively, the various epitaxy layers can be epitaxy grown by another suitable technique, such as hydride vapor phase epitaxy (HVPE) or molecular beam epitaxy (MBE). For example, a GaN layer (such as the buffer layer) can be epitaxy grown by HVPE with source materials including gallium chloride and ammonia gases.

The LED wafer 205 further includes a metal layer 250 and a metal layer 260 disposed over the substrate 210. The metal layer 250 is disposed over the epitaxy layer 240 (in the depicted embodiment, p-GaN layer) and serves as a contact for electrical connection to the epitaxy layer 240, and the metal layer 260 is disposed over the epitaxy layer 220 (in the depicted embodiment, n-GaN layer) and serves as a contact for electrical connection to the epitaxy layer 220. The metal layer 250 may thus be referred to as a p-electrode, and the metal layer 260 may thus be referred to as an n-electrode. The metal layers 250 and 260 may include multiple metal layers or films, each serving various functions. The metal layers 250 and 260 include materials such as nickel (Ni), chromium (Cr), aluminum (Al), titanium (Ti), platinum (Pt), palladium (Pg), gold (Au), silver (Ag), indium (In), zinc (Zn), tin (An), beryllium (Be), indium tin oxide (TTO), alloys thereof, other suitable materials, or combinations thereof. In an example, the metal layer 250 can include a first metal film disposed on the p-GaN layer, a second metal film disposed on the first metal film, and a third metal film disposed over the second metal film. The first metal film serves as a contact to electrically connect the p-GaN layer, and thus, the first metal film is also referred to as a p-GaN contact (or p-electrode). In an example, the first metal film includes a transparent conductive film, such as TTO, formed on the p-GaN layer. In another example, the first metal film includes Ni, Cr, or other suitable metal. The second metal film serves as a reflector disposed on the first metal film. The second metal film (or reflector) has a high reflectivity to light emitted by the LED, thereby increasing light emission efficiency. The second metal film includes aluminum, titanium, platinum, palladium, silver, or other suitable metal. The third metal film serves as bonding metal designed for wafer bonding. The third metal film includes gold (Au), gold tin (AuSn), gold indium (AuIn), or other suitable metal to achieve eutectic bonding or other wafer bonding mechanism. The metal layer 260 may also have multiple metal film layers configured as those described with respect to metal layer 250, and specifically configured to serve as electrical connection to the n-GaN layer. The metal layer 260 may thus be referred to as an n-GaN contact (or n-electrode). The various metal films can be formed by physical vapor deposition (PVD) or other suitable technique.

The LED wafer 205 may further include a passivation layer that seals and protects various features of the LED wafer 205 from other features. The passivation layer includes a dielectric material, such as silicon oxide, silicon nitride, silicon oxynitride, silicon carbide, other suitable dielectric material, or combinations thereof. The LED wafer 205 may further include other features and/or layers depending on design requirements of the LED structure 200.

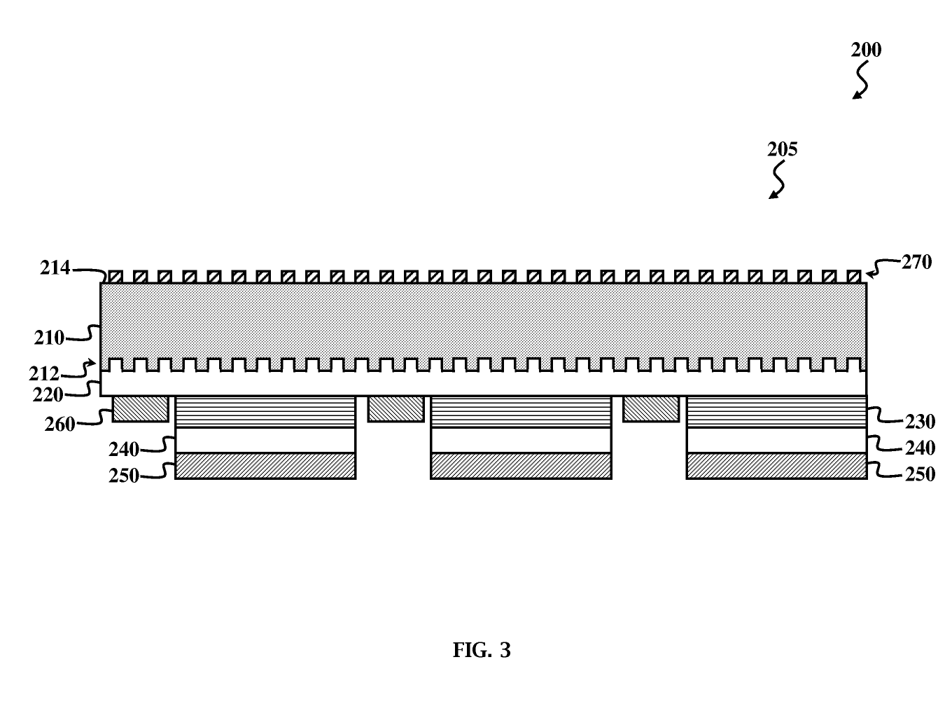

Referring to FIGS. 3-5, a roughening process is applied to the surface 214 of the substrate 210, thereby forming roughened surface 214A. The roughened surface 214A may also be referred to as a patterned surface. In FIG. 3, the LED wafer 205 is upside down where the surface 212 (the “top” surface) appears as the “bottom” surface of the substrate 210 and the surface 214 (the “bottom” surface) appears as the “top” surface of the substrate 210. A patterned metal layer 270 is formed over the surface 214 of the substrate 210. In the depicted embodiment, the patterned metal layer 270 includes nickel (Ni) or chromium (Cr). The patterned metal layer 270 may include other suitable metal materials. The patterned metal layer 270 has a thickness, such as about 100 nm to about 1,000 nm. The patterned metal layer 270 also has a pitch less than or equal to about 2 microns. In an example, the patterned metal layer 270 is formed using a lithography lift-off process. For example, forming the patterned metal layer 270 includes forming a photoresist layer over the surface 214 (such as by spin-coating); patterning the photoresist layer to form one or more openings therein that expose the surface 214 of the substrate 210 (such as by exposing and developing the photoresist layer); depositing a metal layer, such as a Ni or Cr layer, over the photoresist layer, such that the metal layer is formed over the exposed portions of the surface 214; and removing the photoresist layer (for example, using a solvent such as tetramethylammonium hydroxide (TMAH)), which simultaneously removes the metal layer except where the metal layer is deposited on the exposed portions of the surface 214, and thereby leaves the patterned metal layer 270.

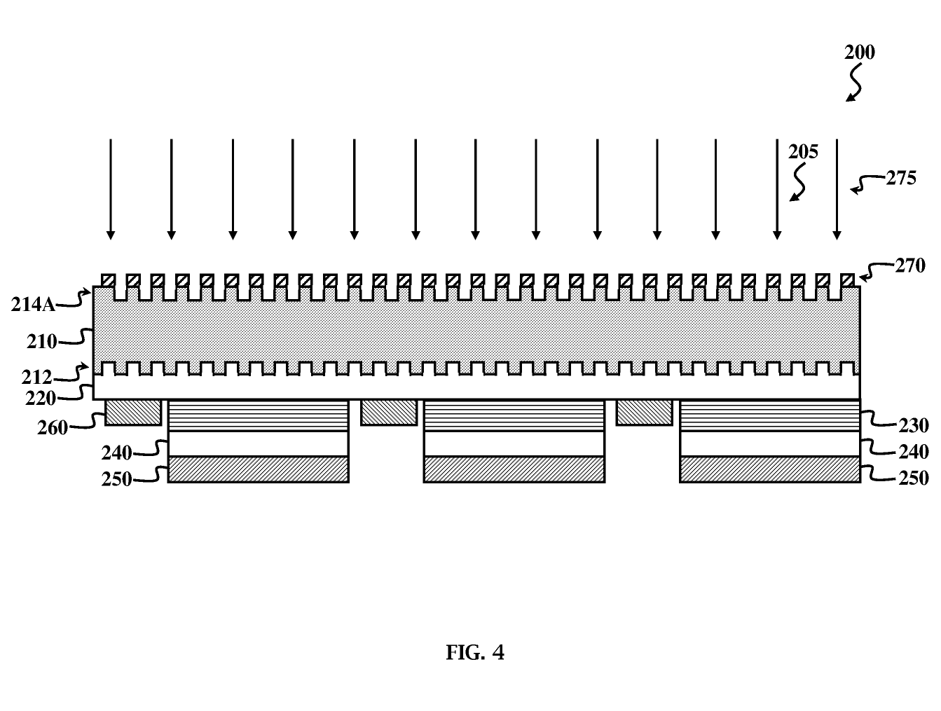

In FIG. 4, an etching process 275 roughens the surface 214 of the substrate 210, thereby forming the roughened (or patterned) surface 214A. The etching process 275 uses the patterned metal layer 270 as an etching mask. In the depicted embodiment, the etching process 275 is a dry etching process. For example, the etching process 275 is an inductively coupled plasma (ICP) reactive ion etching process. The dry etching process has etching parameters that can be tuned to achieve a desired profile for the roughened surface 214A, such as etchants, etching temperature, etching pressure, source power, RF bias voltage, RF bias power, etchant flow rate, and other suitable parameters. In an example, the dry etching process uses chlorine-containing etching gases (such as BCl₃), argon-containing etching gases (such as Ar), other suitable etching gases, or combinations thereof. In an example, the dry etching process is performed for about one hour to about two hours. In an example, the dry etching process includes an etching time of about 20 minutes to about 2 hours, an etching pressure of about 0.5 Pa to about 5 mT, a source power of about 200 W to about 600 W, an RF bias voltage of about 500 V to about 800 V, and a BCl₃ gas flow of about 20 sccm to about 80 sccm.

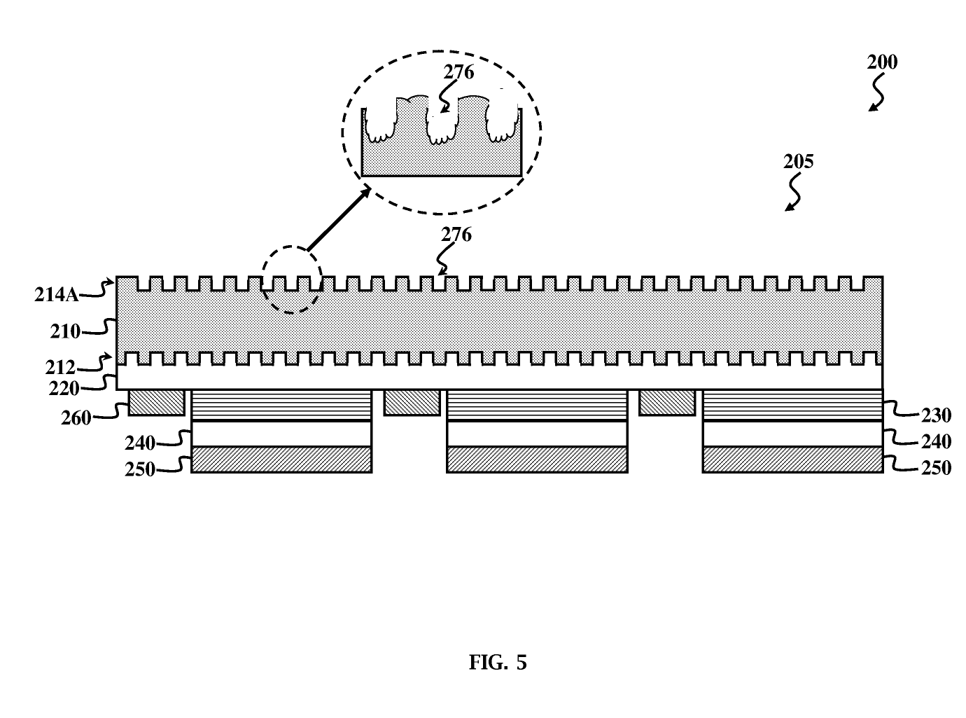

In FIG. 5, in the depicted embodiment, the patterned metal layer 270 is removed after the etching process 275, leaving the roughened surface 214A. The patterned metal layer 270 is removed by a suitable process, such as an etching process that selectively removes the patterned metal layer 270. In another example, the patterned metal layer 270 is removed during the etching process 275. The roughened surface 214A enhances light extraction efficiency of the LED structure 200. As noted, in FIGS. 3-5, the lithography and etching processes are selected to achieve a desired profile for the roughened surface 214A. For example, in the depicted embodiment, using a patterned metal layer 270 having a pitch less than or equal to about 2 microns as the etching mask produces a roughened surface for the LED structure 200 that optimizes light extraction efficiency. The roughened surface 214A includes dips 276. The dips 276 are randomly distributed over the roughened surface 214A of the substrate 210. The dips 276 have peaks and valleys and the valleys are substantially non-symmetrical. In the depicted embodiment, the dips 276 have a depth in the substrate 210 of less than or equal to about 4 microns. In an example, the depth of the dips 276 is from about 3 microns to about 4 microns. The dips 276 are nano-sized, for example, the dips 276 have an average dimension of about 1 nanometer and about 3,000 nanometers, and a width of about 100 nanometers to about 10,000 nanometers. The dips 276 also have an average distance between adjacent dips. For example, the average distance between dips is about 1 nanometer to about 20,000 nanometers.

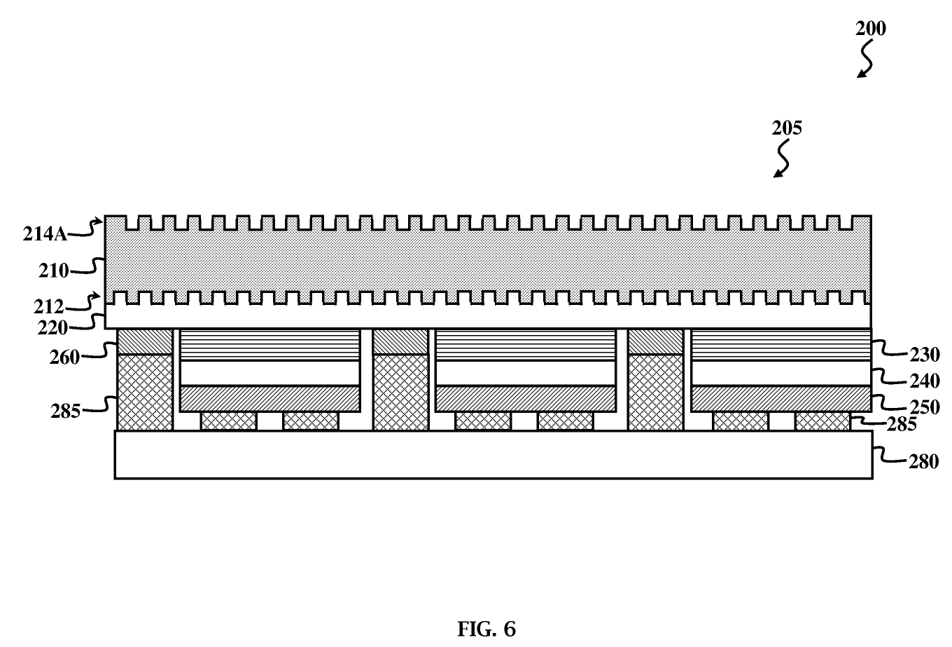

Referring to FIG. 6, the LED wafer 205 is bonded to a substrate 280 via a metal layer 285. The substrate 280 may be referred to as a baseboard. In the depicted embodiment, the substrate 280 includes silicon. The substrate 280 may alternatively or additionally include ceramic, SiC, Ge, AlN, other suitable material, or combinations thereof. In an example, the substrate 280 includes a metal plate or other suitable material with proper material characteristics that provide mechanical strength for securing the LED wafer 205 thereon. The metal layer 285 may be considered a part of the substrate 280, and the metal layer 285 includes a material suitable for bonding to the metal layers 250 and 260, such as Au, AuSn, AuIn, other suitable bonding metal, or combinations thereof. Such bonding may provide electrical coupling of the LED wafer 205 and substrate 280. The metal layer 285 may be referred to as a conductive terminal, where in the depicted embodiment, the metal layer 285 includes a conductive terminal that connects the substrate 280 with the metal layer 250 (for example, the p-GaN contact (or p-electrode)) and a conductive terminal that connects the substrate 280 with the metal layer 260 (for example, the n-GaN contact (or n-electrode)), such that the conductive terminals are connected to opposite contacts of the LED wafer 205 (an n-type contact and a p-type contact). The conductive terminals are thus connected to opposite junctions of the LED wafer 205. The bonding material of the metal layer 285 can be the same or different from bonding metal of the metal layers 250 and 260 in terms of composition, depending on the desired wafer bonding mechanism and specifications for the LED structure 200. For example, the metal layer 285 and metal layers 250 and 260 can be paired to achieve eutectic wafer bonding. In an example, the wafer bonding process implements thermal annealing and applying a mechanical pressure during the thermal annealing, which can increase bonding strength. In the depicted embodiment, the wafer bonding process uses a flip-chip process, where the LED wafer 205 is flipped upside down and aligned with the substrate 280, such that the surface 212 appears as the “bottom” surface of the substrate 210 and the surface 214A appears as the “top” surface of the substrate 210. Alternatively, other processes may be implemented to bond the LED wafer 205 with the substrate 280. The LED structure 200 is thus a flip-chip LED structure, where the epitaxial structure (epitaxial layers 230, 240, and 250) is disposed between the roughened surface 212A and the substrate 280.

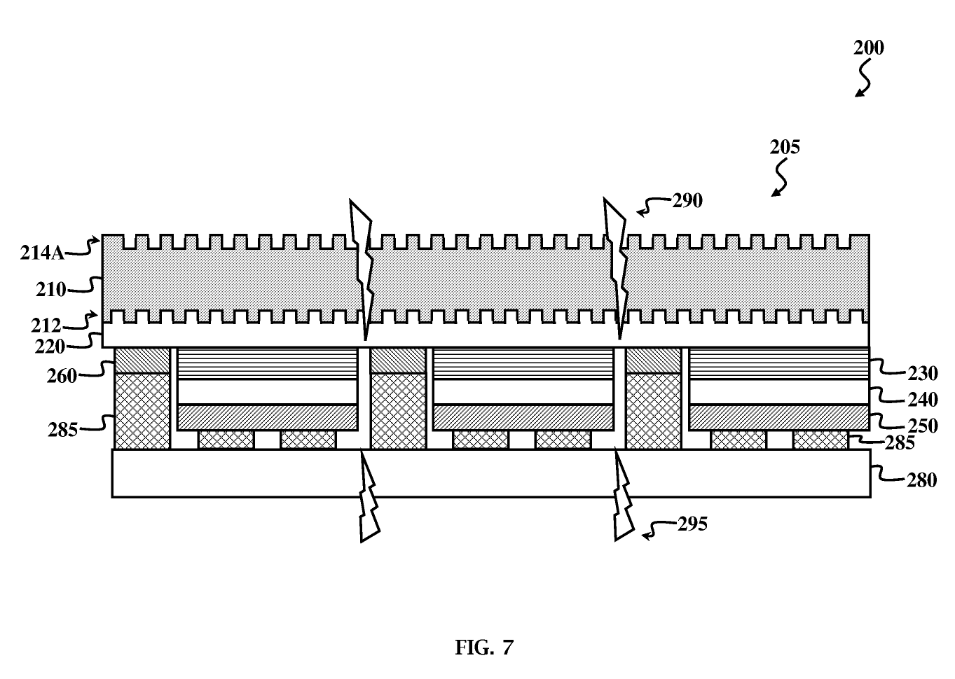

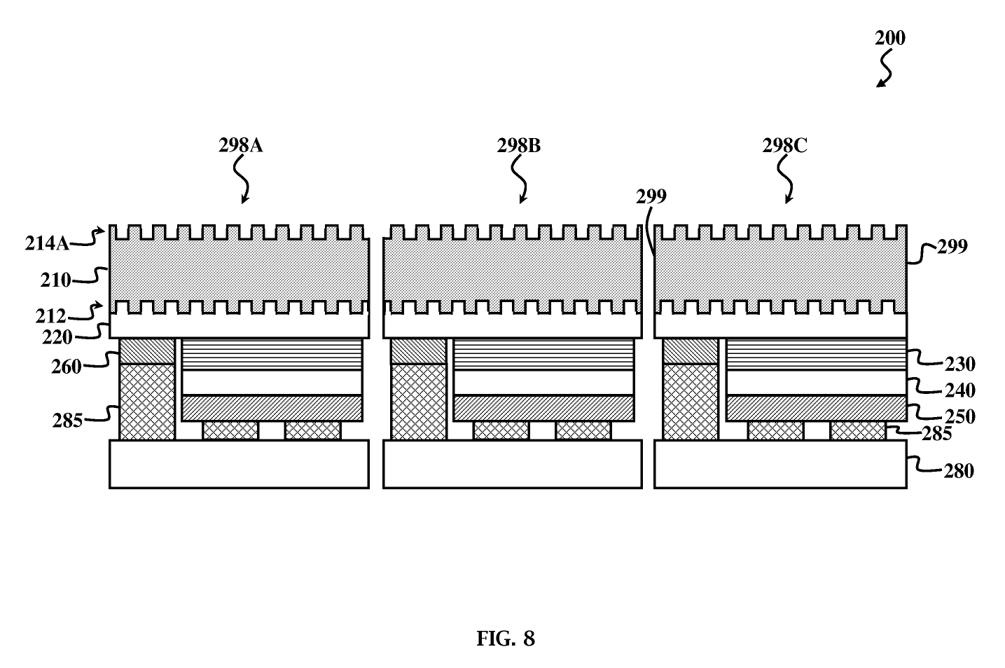

Referring to FIG. 7 and FIG. 8, the LED structure 200 is separated (singulated) into LED dies. More specifically, a singulating process 290 is applied to the LED wafer 205, and a singulating process 295 is applied to the substrate 280, thereby forming individual LED dies 298A, 298B, and 298C. The singulating processes 290 and 295 may be the same or different processes, and may be performed simultaneously or independently. The singulating processes 290 and 295 include mechanical blade dicing (such as diamond blade sawing), mechanical scribe-and-break, laser scribe-and-break, plasma dicing, other suitable singulating processes, or combinations thereof. In the depicted embodiment, the singulating processes 290 and 295 are laser scribe-and-break processes. Specifically, the singulating processes 290 and 295 use a stealth dicing laser system to laser scribe the LED wafer 205 and the substrate 280, and then a breaker system to break the LED wafer 205/substrate 280 into the individual LED dies 298A, 298B, and 298C. For example, a stealth dicing technique focuses an output of a picosecond laser inside the substrate 210 of the LED wafer 205 to create cracks within the substrate 210 without affecting the roughened surfaces 212A and 214A of the substrate 210, and then breaking the substrate 210 along such cracks. Similarly, the stealth dicing technique may be used to focus the output of the picosecond laser inside the substrate 280 to create cracks within the substrate 280 without affecting surfaces of the substrate 280. The stealth dicing technique used to singulate the LED structure 200 into individual LED dies 298A, 298B, and 298C is further described in U.S. patent application Ser. No. 13/276,108, filed on Oct. 18, 2011, entitled “Thick Window Layer LED Manufacture,” the entire disclosure of which is incorporated herein by reference. In an example, the LED wafer 205 and the substrate 280 are simultaneously scribed and broken into the individual LED dies 298A, 298B, and 298C. In another example, the LED wafer 205 and the substrate 280 are individually scribed and then simultaneously broken. In yet another example, the LED wafer 205 is scribed using the stealth dicing technique, the substrate 280 is scribed using a conventional laser scribing technique, and the LED wafer 205 and substrate 280 are simultaneously broken.

Using the stealth dicing technique to singulate the LED structure 200 into the LED dies 298A, 298B, and 298C eliminates the need to thin the substrate 210 (here, the sapphire substrate) of the LED wafer 205. The substrate 210 of the LED dies 298A, 298B, and 298C can thus have a thickness greater than conventional LED dies, for example, a thickness greater than or equal to about 250 μm. The greater thickness can enhance light extraction efficiency. Further, using the stealth dicing technique to singulate the LED structure 200 also provides the LED dies 298A, 298B, and 298C with high quality edges. For example, in the depicted embodiment, sidewalls (or edges) 299 of the LED dies 298A, 298B, and 298C (particularly the substrate 210 of the LED wafer 205) are substantially debris-free, having minimal residual stress and/or thermal damage. More specifically, the stealth dicing technique does not induce laser charred marks on the sidewalls (or edges) of the substrate 210 of the LED wafer 205, which typically arises from conventional laser scribing techniques. Such characteristics may also be observed in sidewalls (edges) of the substrate 280, where the singulating process 295 implements a stealth dicing technique.

It is noted that, in the depicted embodiment, the entire LED wafer 205 is bonded to the substrate 280, and then, the LED wafer 205 and substrate 280 are singulated to form the various LED dies 298A, 298B, and 298C. Alternatively, before bonding the LED wafer 205 to the substrate 280, the LED wafer 205 is subjected to a singulation process to form individual LED devices (which can also be referred to as LED dies), and then, the individual LED devices are bonded to the substrate 280. After the individual LED dies are bonded to the substrate 280, the substrate 280 may then be subjected to a singulation process to provide the individual LED dies 298A, 298B, and 298C. The singulation processes include mechanical blade dicing (such as diamond blade sawing), mechanical scribe-and-break, laser scribe-and-break, plasma dicing, other suitable singulating processes, or combinations thereof. In an example, the LED wafer 205 is subjected to a singulating process that implements a stealth dicing and breaking process, and the substrate 280 is subjected to a singulating process that implements a conventional laser scribing and breaking process. In another example, the singulating processes for both the LED wafer 205 and the substrate 280 implement a stealth dicing and breaking process.

By implementing the foregoing process, each of the LED dies 298A, 298B, and 298C includes the substrate 210 having double roughened surfaces (roughened surface 212 and roughened surface 214A), a thickness greater than or equal to about 250 μm, and high quality edges 299. The double roughened surfaces of the substrate 210 can increase light output power, when compared to LED devices having a single roughened surface. Further, as noted above, the greater thickness and high quality edges of the substrate 210 can increase light output power. The LED dies 298A, 298B, and 298C thus exhibit increased light output power, including enhanced light extraction efficiency (such as enhanced internal and/or external quantum efficiency). Different embodiments may have different advantages, and no particular advantage is necessarily required of any embodiment.

Thereafter, various packaging processes are implemented to package the LED dies 298A, 298B, and 298C (also referred to as LED chips 298A, 298B, and 298C) for various applications. For example, a packaging process may include attaching one of the LED dies to a packaging substrate, wiring the LED die for electrical connection, applying a phosphor layer around the LED die for tuning a wavelength of light emitted from the LED die, and forming a lens over the LED die, for example, to provide efficient light emission. Other packaging processes are contemplated by the present disclosure.

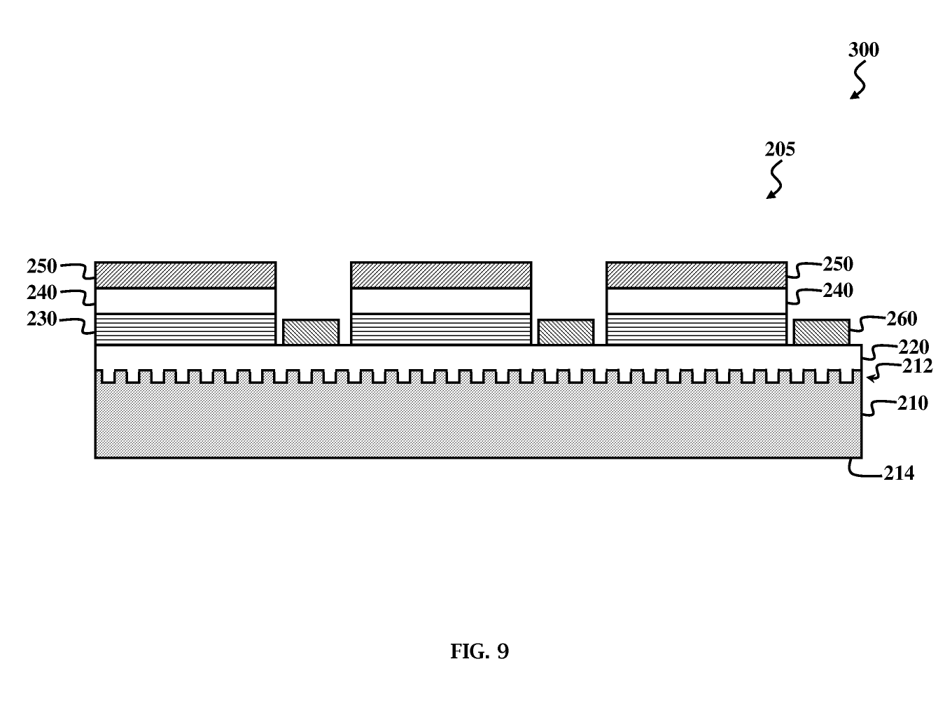

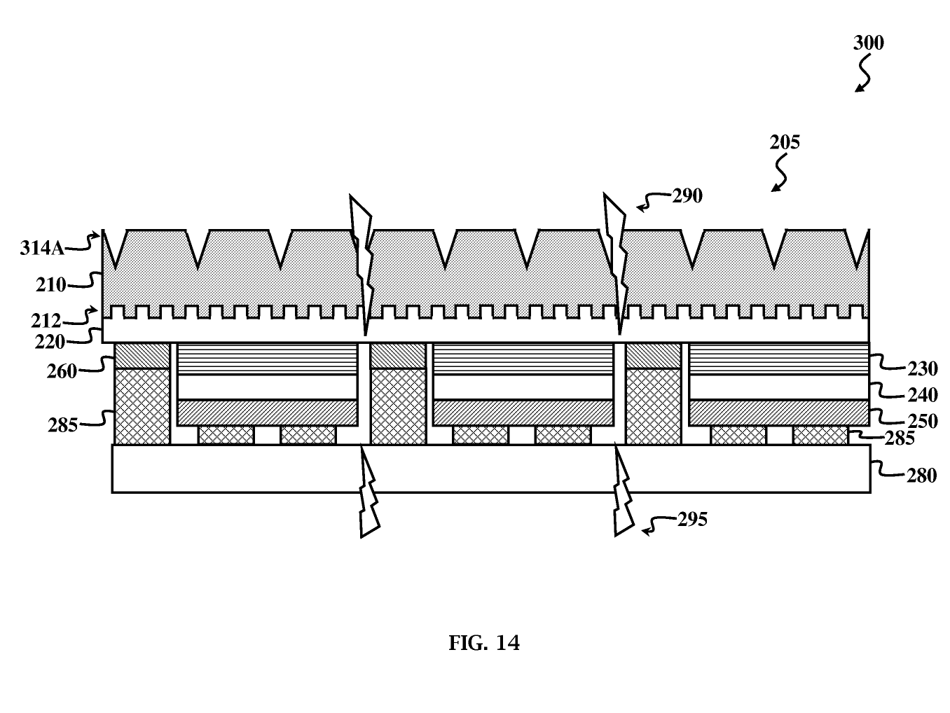

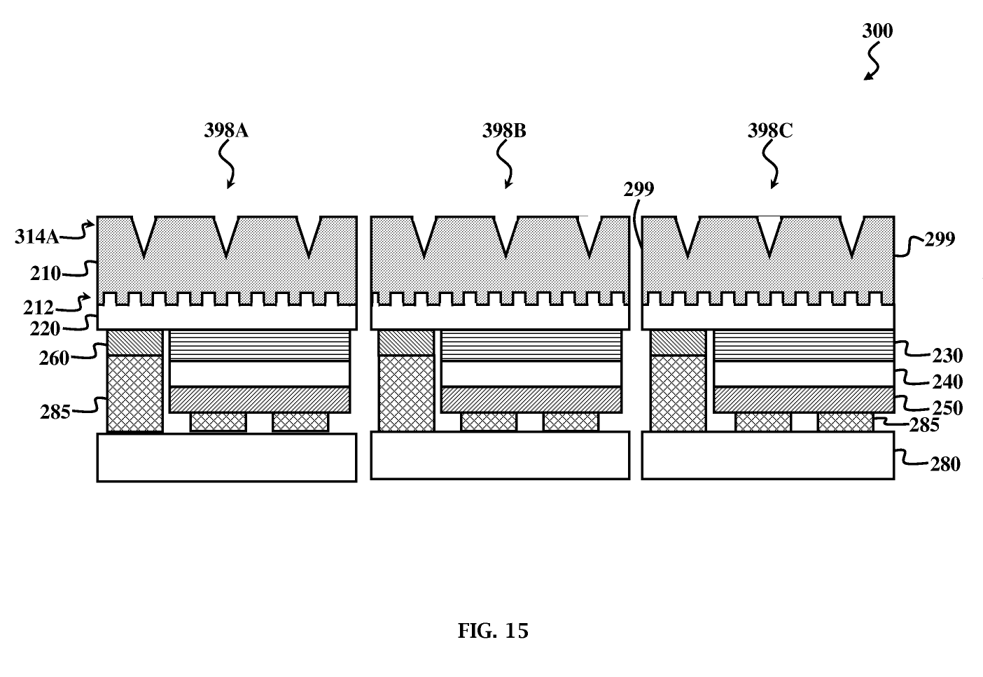

FIGS. 9-15 are various diagrammatic cross-sectional views of another embodiment of an LED structure 300, in portion or entirety, during various fabrication stages according to the method 100 of FIG. 1. The embodiment of FIGS. 9-15 is similar in many respects to the embodiment of FIGS. 2-8. Accordingly, similar features in FIGS. 2-8 and 9-15 are identified by the same reference numerals for clarity and simplicity. FIGS. 9-15 have been simplified for the sake of clarity to better understand the inventive concepts of the present disclosure. Additional features can be added in the LED structure 300, and some of the features described below can be replaced or eliminated in other embodiments of the LED structure 300.

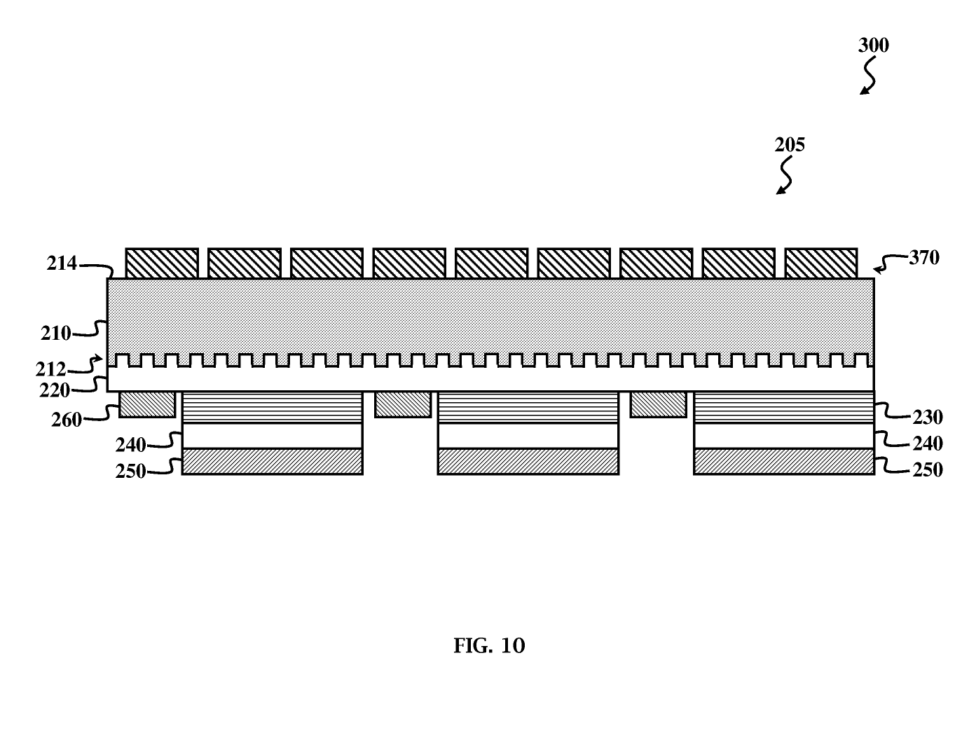

Referring to FIG. 9, the LED structure 300 includes the LED wafer 205. Referring to FIGS. 10-12, a roughening process is applied to the surface 214 of the substrate 210, thereby forming a roughened surface 314A. The roughening process illustrated in FIGS. 10-12 is different than the roughening process described above with reference to FIGS. 3-5 and will be described further below. The roughened surface 314A may also be referred to as a patterned surface. In FIG. 10, the LED wafer 205 is upside down where the surface 212 (the “top” surface) appears as the “bottom” surface of the substrate 210 and the surface 214 (the “bottom” surface) appears as the “top” surface of the substrate 210. A patterned hard mask layer 370 is formed over the surface 214 of the substrate 210. In the depicted embodiment, the patterned hard mask layer 270 includes silicon nitride (SiN). Alternatively or additionally, the patterned hard mask layer 270 includes silicon oxynitride, silicon oxide (SiO₂), silicon carbide, other suitable material, or combinations thereof. The patterned hard mask layer 370 has a thickness, such as about 1 micron to about 10 microns. The patterned hard mask layer 370 also has a pitch less than or equal to about 50 microns. In an example, the patterned hard mask layer 370 is formed using lithography processing. For example, forming the patterned hard mask layer 370 includes forming a hard mask layer over the surface 214 of the substrate 210; forming a photoresist layer over the surface hard mask layer (such as by spin-coating); patterning the photoresist layer to form one or more openings therein that expose the hard mask layer (such as by exposing and developing the photoresist layer); etching the exposed hard mask layer using the photoresist layer as an etching mask; and removing the patterned photoresist layer, thereby leaving the patterned hard mask layer 370. Other lithography processing methods may be implemented to form the patterned hard mask layer 370.

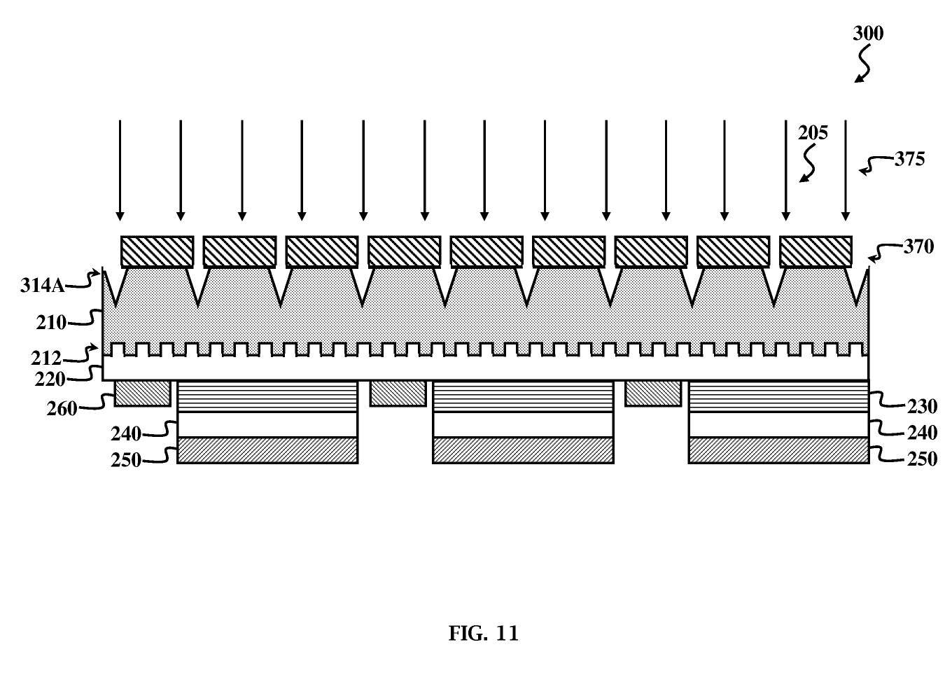

In FIG. 11, an etching process 375 roughens the surface 214 of the substrate 210, thereby forming the roughened (or patterned) surface 314A. The etching process 375 uses the patterned hard mask layer 370 as an etching mask. In the depicted embodiment, the etching process 375 is a wet etching process. The wet etching process has etching parameters that can be tuned to achieve a desired profile for the roughened surface 314A, such as etching solutions, etching temperature, etching time, and other suitable parameters. In the depicted embodiment, the wet etching solutions include H₂SO₄ (sulfuric acid), H₂PO₃ (phosphoric acid), other suitable wet etching solutions, or combinations thereof. The etching temperature may be about 250° C. to about 300° C. The etching time may be greater than or equal to about two hours. In an example, the LED wafer 205 is immersed in a 1:1 mixture of H₂SO₄ and H₂PO₃ at a temperature of about 200° C. to about 250° C. for about 2 hours.

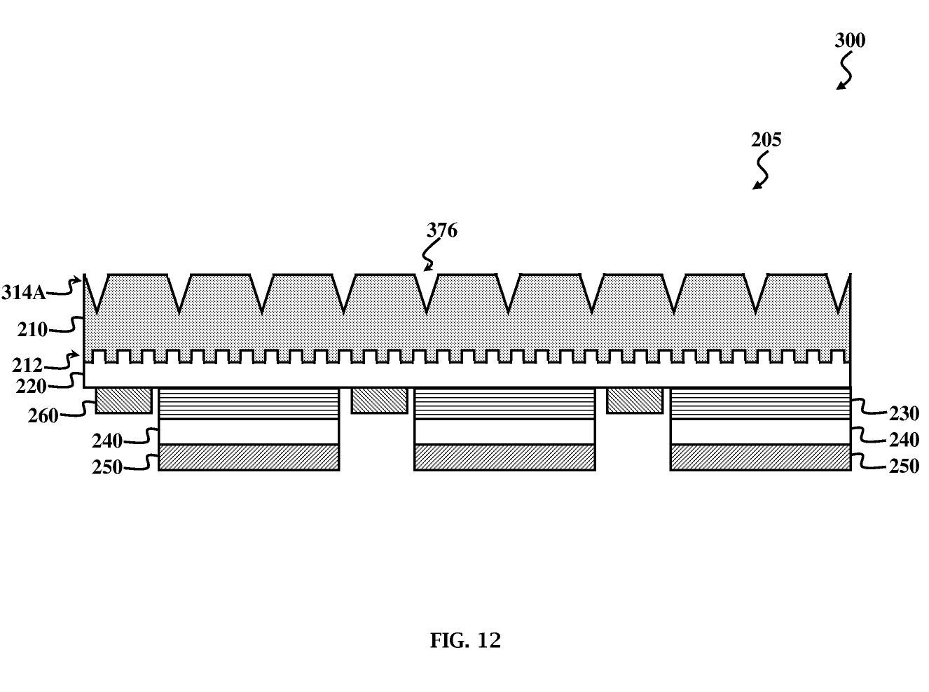

In FIG. 12, the patterned hard mask layer 370 is removed. In the depicted embodiment, the patterned hard mask layer 370 is removed during the etching process 375, leaving the roughened surface 314A. A subsequent etching process may be performed to remove any residue of the patterned hard mask layer 370. In another example, another etching process is used to remove the patterned hard mask layer 370 after the etching process 375. The roughened surface 314A enhances light extraction efficiency of the LED structure 300. In FIGS. 10-12, the lithography and etching processes are selected to achieve a desired profile for the roughened surface 314A. For example, in the depicted embodiment, using a patterned hard mask layer 370 having a pitch less than or equal to about 50 microns as the etching mask produces a roughened surface for the LED structure 300 that optimizes light extraction efficiency. The roughened surface 314A includes dips 376. The dips 376 are randomly distributed over the roughened surface 314A of the substrate 210. In the depicted embodiment, facets (sidewalls) of the dips 376 follow a crystal orientation of the substrate 210. The etching process 375 is tuned such that the facets (sidewalls) of the dips 376 taper to a point at a depth in the substrate 210. In the depicted embodiment, the dips 376 have a depth in the substrate 210 of less than or equal to about 4 microns. In an example, the depth of the dips 376 is from about 3 microns to about 4 microns. The dips 376 are nano-sized, for example, the dips 376 have an average dimension ranging between about 1 nanometer and about 10,000 nanometers, and a width of about 100 nanometers to about 10,000 nanometers. The dips 376 also have an average distance between adjacent dips. For example, the average distance between dips is about 500 nanometers to about 50,000 nanometers.

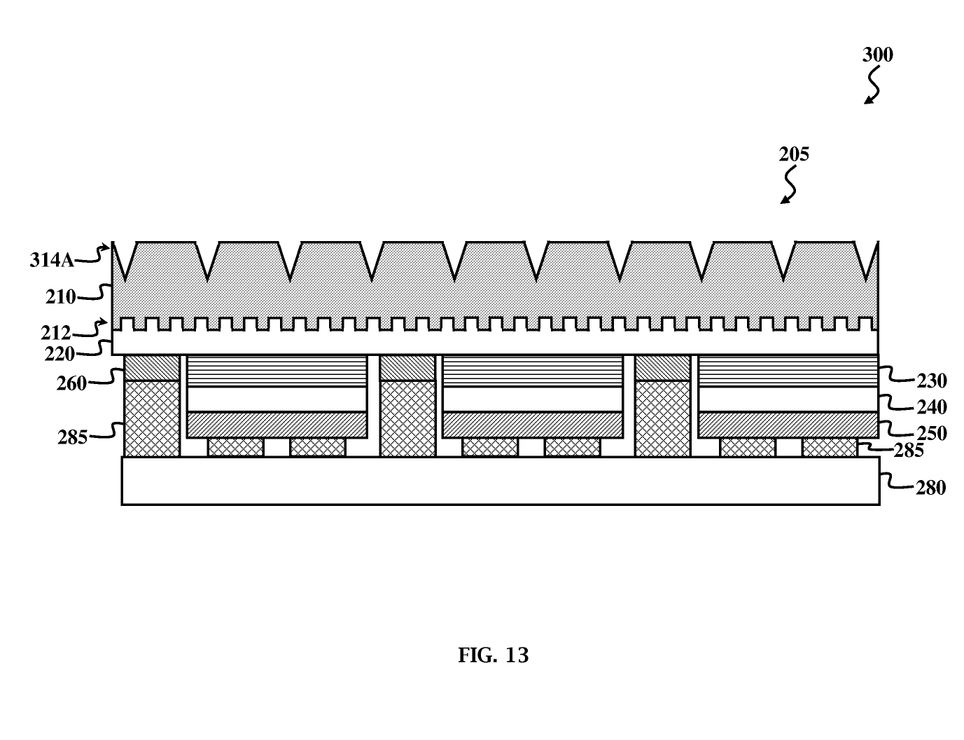

Referring to FIGS. 13-15, similar to the LED structure 200 in FIGS. 7-9, the LED structure 300 is separated (singulated) into LED dies. For example, the LED wafer 205 is bonded to the substrate 280, and the singulation processes 290 and 295 are performed on the LED wafer 205 (specifically substrate 210) and the substrate 280 to provide individual LED dies 398A, 398B, and 398C. By implementing the foregoing process, each of the LED dies 398A, 398B, and 398C includes the substrate 210 having double roughened surfaces (roughened surface 212 and roughened surface 314A), a thickness greater than or equal to about 250 μm, and high quality edges 299. The double roughened surfaces of the substrate 210 can increase light output power, when compared to LED devices having a single roughened surface. Further, as noted above, the greater thickness and high quality edges of the substrate 210 can increase light output power. The LED dies 398A, 398B, and 398C thus exhibit increased light output power, including enhanced light extraction efficiency (such as enhanced internal and/or external quantum efficiency). Different embodiments may have different advantages, and no particular advantage is necessarily required of any embodiment.

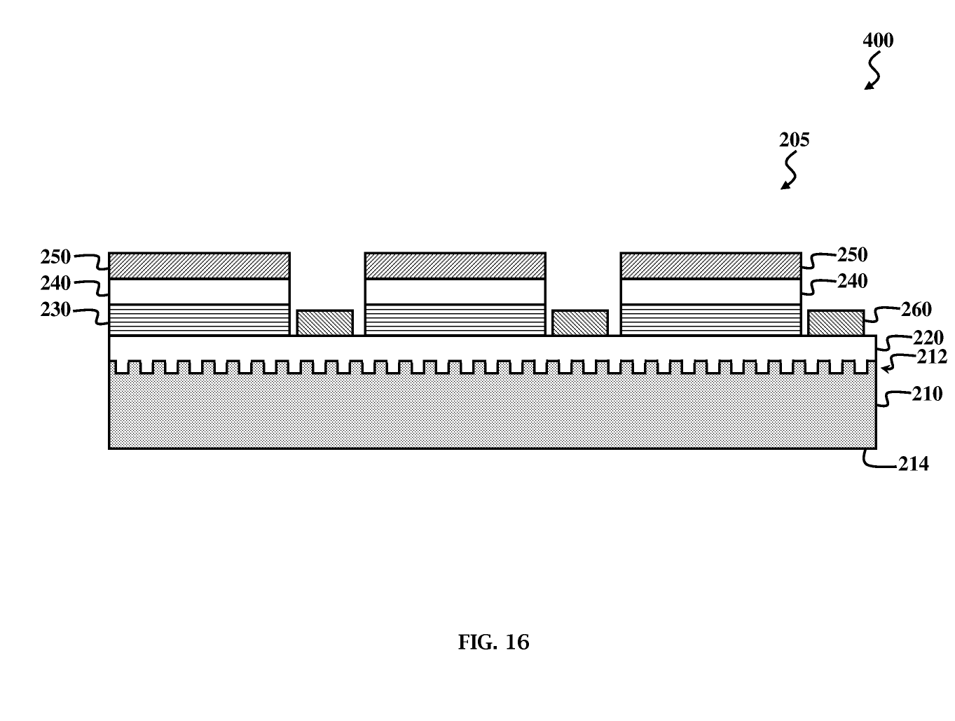

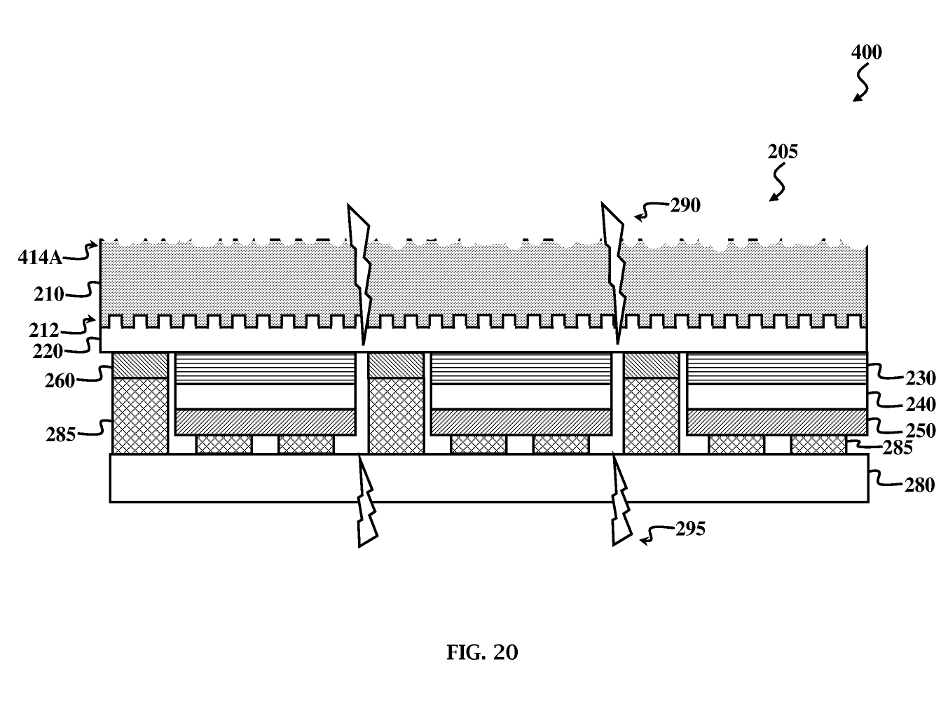

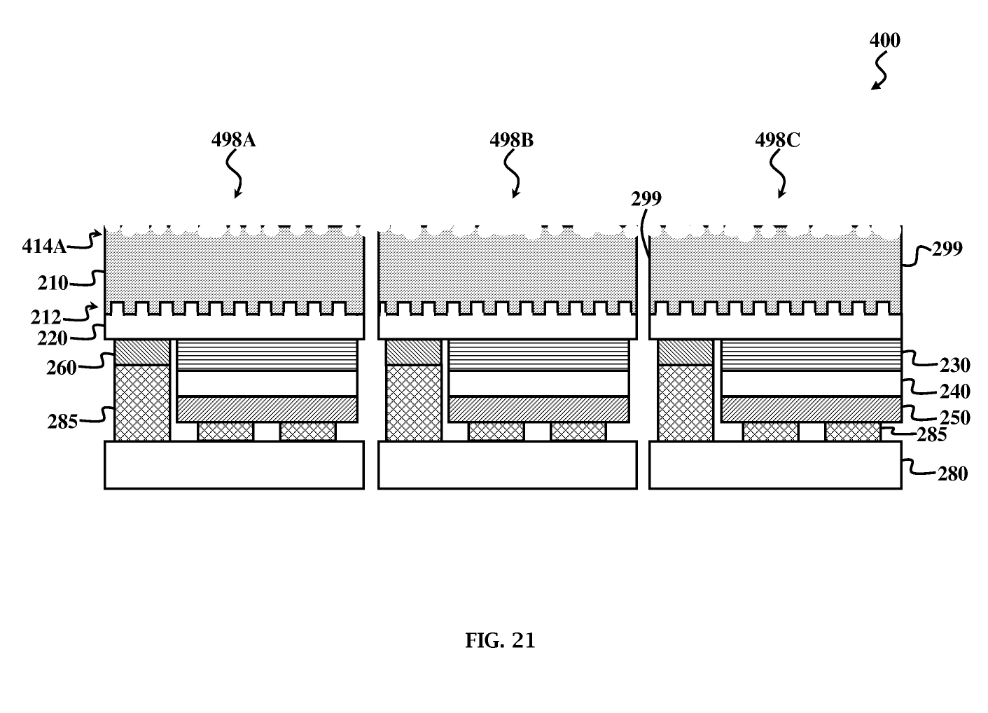

FIGS. 16-21 are various diagrammatic cross-sectional views of yet another embodiment of an LED structure 400, in portion or entirety, during various fabrication stages according to the method 100 of FIG. 1. The embodiment of FIGS. 16-21 is similar in many respects to the embodiment of FIGS. 2-8. Accordingly, similar features in FIGS. 2-8 and 16-21 are identified by the same reference numerals for clarity and simplicity. FIGS. 16-21 have been simplified for the sake of clarity to better understand the inventive concepts of the present disclosure. Additional features can be added in the LED structure 400, and some of the features described below can be replaced or eliminated in other embodiments of the LED structure 400.

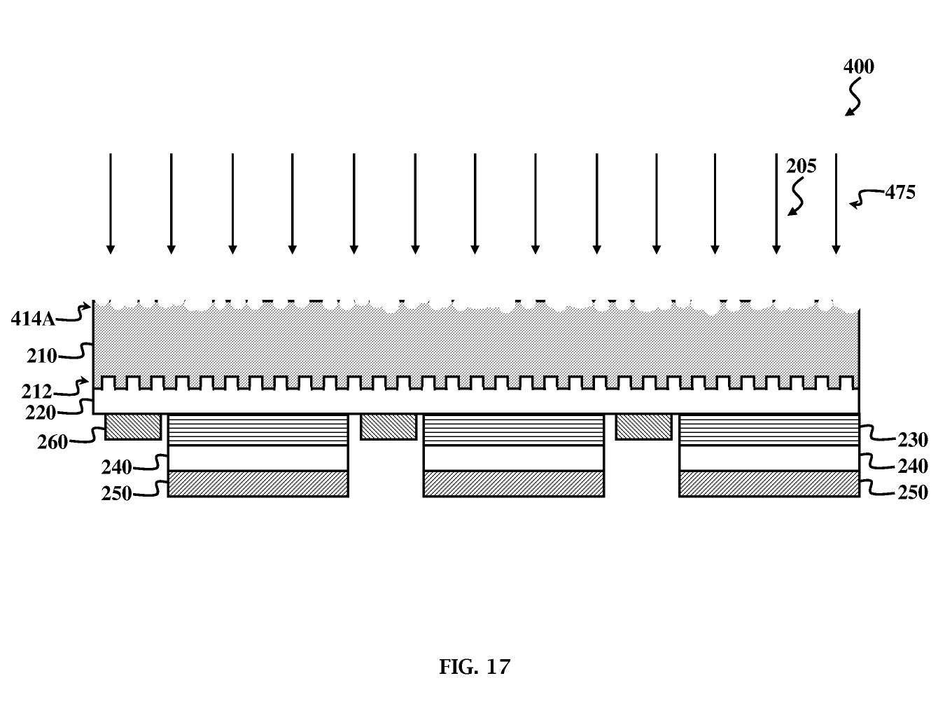

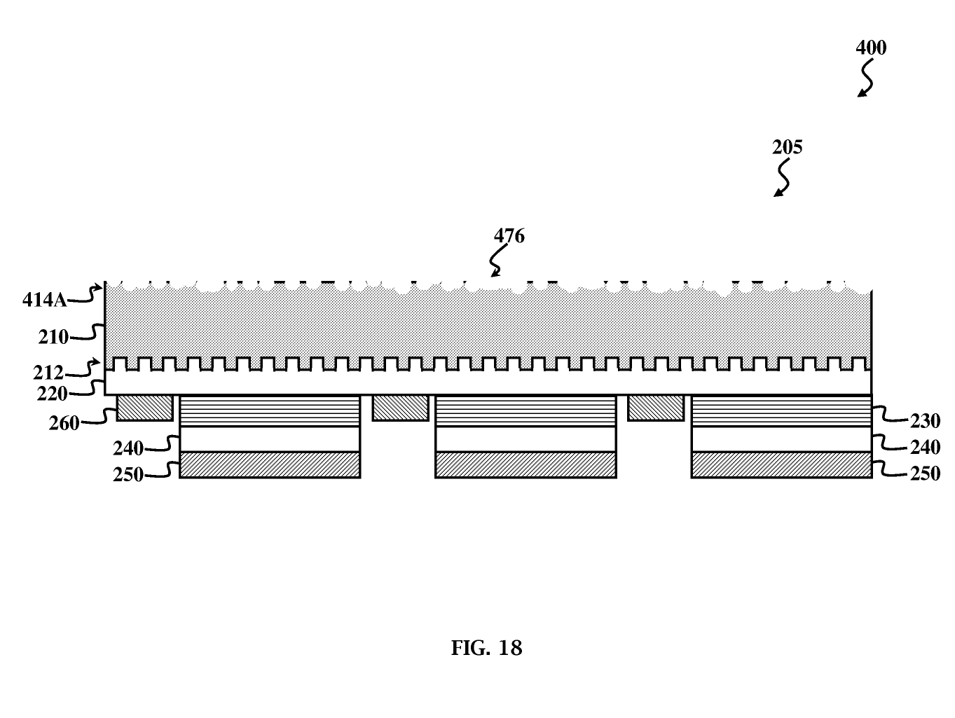

Referring to FIG. 16, the LED structure 400 includes the LED wafer 205. Referring to FIG. 17 and FIG. 18, a roughening process is applied to the surface 214 of the substrate 210, thereby forming a roughened surface 414A. The roughening process illustrated in FIGS. 17 and 18 is different than the roughening process described above with reference to FIGS. 3-5 and will be described further below. The roughened surface 414A may also be referred to as a patterned surface. In FIG. 17, the LED wafer 205 is upside down where the surface 212 (the “top” surface) appears as the “bottom” surface of the substrate 210 and the surface 214 (the “bottom” surface) appears as the “top” surface of the substrate 210. A lapping process 475 roughens the surface 214 of the substrate 210, thereby forming the roughened (or patterned) surface 414A. The lapping process 475 uses a nano-particle slurry. The nano-particle slurry uses particles having a particle size less than or equal to about 5 microns. In the depicted embodiment, the nano-particle slurry is a nano-particle alumina (Al₂O₃) slurry. Alternatively, the nano-particle slurry is a nano-particle diamond (C) slurry, nano-particle silicon carbide (SiC) slurry, a nano-particle boron carbide slurry, or other suitable nano-particle slurry. In an example, the lapping process 475 rotates a lapping plate at a speed of about 10 rpm to about 500 rpm. In an example, the lapping process 475 is performed on the surface 214 of the substrate 210 for about 30 minutes to about 180 minutes. A grinding process may be implemented on the surface 214, for example, to thin the substrate 210, before the lapping process 475. The grinding process uses a slurry having a particle size greater than or equal to about 3 microns. For example, the grinding process may use a diamond grinding plate. In an example, the grinding process rotates a grinding plate at a speed of about 100 rpm to about 2,000 rpm. In an example, the grinding process is performed for about 5 minutes to about 60 minutes.

The roughened surface 414A enhances light extraction efficiency of the LED structure 400. The lapping process is selected to achieve a desired profile for the roughened surface 414A. In FIG. 18, the roughened surface 414A includes dips 476. The dips 476 are randomly distributed over the roughened surface 414A of the substrate 210. The dips 476 are nano-sized, for example, the dips 476 have an average dimension ranging between about 1 nanometer and about 3,000 nanometers. In the depicted embodiment, the dips 476 have a depth in the substrate 210 of less than or equal to about 4 microns. In an example, the depth of the dips 476 is from about 3 microns to about 4 microns. The dips 476 also have an average distance between adjacent dips. For example, the average distance between dips is about 200 nanometers to about 5,000 nanometers.

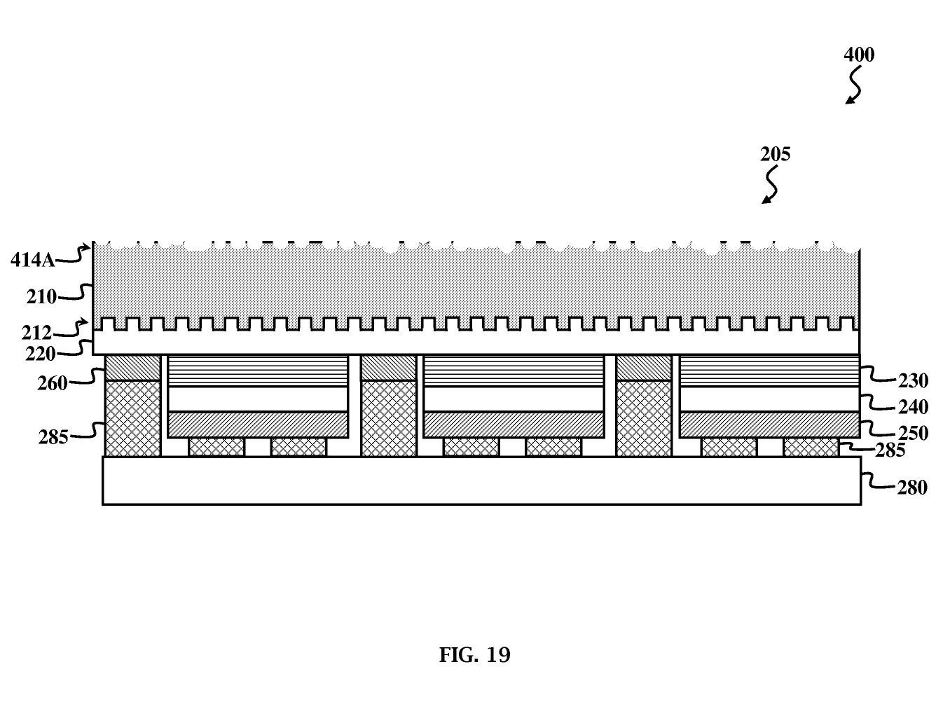

Referring to FIGS. 19-21, similar to the LED structure 200 in FIGS. 7-9, the LED structure 400 is separated (singulated) into LED dies. For example, the LED wafer 205 is bonded to the substrate 280, and the singulation processes 290 and 295 are performed on the LED wafer 205 (specifically substrate 210) and the substrate 280 to provide individual LED dies 498A, 498B, and 498C. By implementing the foregoing process, each of the LED dies 498A, 498B, and 498C includes the substrate 210 having double roughened surfaces (roughened surface 212 and roughened surface 414A), a thickness greater than or equal to about 250 μm, and high quality edges 299. The double roughened surfaces of the substrate 210 can increase light output power, when compared to LED devices having a single roughened surface. Further, as noted above, the greater thickness and high quality edges of the substrate 210 can increase light output power. The LED dies 498A, 498B, and 498C thus exhibit increased light output power, including enhanced light extraction efficiency (such as enhanced internal and/or external quantum efficiency). Different embodiments may have different advantages, and no particular advantage is necessarily required of any embodiment.

The present disclosure provides for many different embodiments. For example, the present disclosure provides for various LED structures and methods of manufacturing the same. An exemplary LED structure includes a crystalline substrate having a thickness that is greater than or equal to about 250 μm, wherein the crystalline substrate has a first roughened surface and a second roughened surface, the second roughened surface being opposite the first roughened surface; a plurality of epitaxy layers disposed over the first roughened surface, the plurality of epitaxy layers being configured as a light emitting diode; and another substrate bonded to the crystalline substrate such that the plurality of epitaxy layers are disposed between the another substrate and the first roughened surface of the crystalline substrate. Sidewalls of the crystalline substrate may be substantially free of laser charred marks. The crystalline substrate may be a sapphire substrate, and the another substrate may include silicon. The thickness of the crystalline substrate may be about 250 μm to about 600 μm. In an example, the second roughened surface includes a plurality of randomly distributed nano-sized dips. The randomly distributed nano-sized dips may have an average dimension of about 1 nanometer to about 10,000 nanometers, an average width of about 100 nanometers and about 10,000 nanometers, and/or a depth of the randomly distributed nano-sized dips is less than or equal to about 4 microns. An average distance between the randomly distributed nano-sized dips may be about 200 nanometers to about 50,000 nanometers.

Another exemplary LED structure includes a baseboard; and an LED device faced-down and electrically coupled to the baseboard. The LED device includes a sapphire substrate having a thickness greater than or equal to about 250 μm, wherein the sapphire substrate includes a first roughened surface and a second roughened surface, the second roughened surface being opposite the first roughened surface, and further wherein the sapphire substrate includes sidewalls that extend between the first roughened surface and the second roughened surface that are substantially free of laser charring; and an epitaxial structure disposed over the first roughened surface of the sapphire substrate, wherein the epitaxial structure is disposed between the baseboard and the first roughened surface. The baseboard may be a silicon substrate. The second roughened surface may include a plurality of randomly distributed nano-sized dips. In an example, the randomly distributed nano-sized dips include peaks and valleys, the valleys being substantially non-symmetrical. In another example, the randomly distributed nano-sized dips include facets that follow a crystal orientation of the sapphire substrate.

An exemplary method for manufacturing the LED structures described herein includes forming an epitaxial structure over a first roughened surface of a first substrate, wherein the epitaxial structure is configured as a LED; forming a roughened second surface of the first substrate, wherein the roughened second surface is opposite the first roughened surface; bonding the first substrate to a second substrate, such that the epitaxial structure is disposed between the first roughened surface of the first substrate and the second substrate; and singulating the first substrate and the second substrate to form LED dies, wherein the singulating the first substrate includes using a stealth dicing technique. Various methods for forming the roughened surface are provided. The roughening methods include a dry etching process that uses a patterned metal layer as an etching mask, a wet etching process that uses a patterned hard mask layer as an etching mask, and a lapping process that uses a nano-particle slurry.

In an example, a method includes forming a plurality of epitaxy layers over a first surface of a substrate, the plurality of epitaxy layers being configured to form a light emitting diode; forming a patterned metal layer over a second surface of the substrate, the second surface being opposite the first surface, wherein the patterned metal layer has openings therein that expose the substrate; and performing a dry etching process to remove portions of the exposed substrate, thereby forming a roughened second surface of the substrate, wherein the dry etching process uses the patterned metal layer as an etching mask. The method may further include roughening the first surface of the substrate before forming the plurality of epitaxy layers thereover. In an example, the method further includes bonding the substrate to another substrate, such that the plurality of epitaxy layers are disposed between the first surface of the substrate and the another substrate. The substrate may be a sapphire substrate. The patterned metal layer may include nickel, chromium, or a combination thereof. Forming the patterned metal layer may include using a lift-off process. In an example, the dry etching process uses a chlorine-containing etching gas, an argon-containing etching gas, or combination thereof.

In another example, a method includes forming a plurality of epitaxy layers over a first surface of a substrate, the plurality of epitaxy layers being configured to form a light emitting diode; and performing a lapping process using a nano-particle slurry on a second surface of the substrate, the second surface being opposite the first surface, thereby forming a roughened second surface of the substrate. The method may further include roughening the first surface of the substrate before forming the plurality of epitaxy layers thereover. The method may further include performing a grinding process on the second surface of the substrate before performing the lapping process. The nano-particle slurry has a particle size less than or equal to about 1 micron. In an example, the nano-particle slurry is a nano-particle Al₂O₃ slurry. The roughened second surface includes a plurality of nano-scale dips in the substrate. The substrate may be a sapphire substrate.

In yet another example, a method includes forming a plurality of epitaxy layers over a first surface of a substrate, the plurality of epitaxy layers being configured to form a light emitting diode; forming a patterned hard mask layer over a second surface of the substrate, the second surface being opposite the first surface, wherein the patterned hard mask layer has openings therein that expose the substrate; performing a wet etching process to remove portions of the exposed substrate, thereby forming a roughened second surface of the substrate, wherein the wet etching process uses the patterned hard mask layer as an etching mask; and bonding the substrate to another substrate, such that the plurality of epitaxy layers are disposed between the first surface of the substrate and the another substrate. The method may further include roughening the first surface of the substrate before forming the plurality of epitaxy layers thereover. The patterned resist layer may be a patterned silicon nitride layer or a patterned silicon oxide layer. In an example, the wet etching process uses a wet etching solution that includes sulfuric acid (H₂SO₄), phosphoric acid (H₂PO₃), or combination thereof. In an example, the wet etching process simultaneously removes the patterned hard mask layer. The wet etching process may form a plurality of dips in the substrate, wherein the plurality of dips have facets in crystal planes of the substrate.

In yet another example, a light emitting diode (LED) structure includes a crystalline substrate having a first roughened surface and a second roughened surface, the second roughened surface being opposite the first roughened surface; a plurality of epitaxy layers disposed over the first roughened surface, the plurality of epitaxy layers being configured to form a light emitting diode; and another substrate bonded to the crystalline substrate, such that the plurality of epitaxy layers are disposed between the another substrate and the first roughened surface of the crystalline substrate. The second surface includes a plurality of randomly distributed dips having an average dimension ranging between about 1 nanometer and about 5,000 nanometers. The crystalline substrate may be a sapphire substrate. An average distance between the dips is about 500 nanometers to about 10,000 nanometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light emitting diode (LED) structure, comprising:
a sapphire substrate having a thickness that is greater than or equal to about 250 μm, wherein the sapphire substrate has a first roughened surface and a second roughened surface, the second roughened surface being opposite the first roughened surface;
a plurality of epitaxy layers disposed over the first roughened surface, the plurality of epitaxy layers being configured as a light emitting diode; and
another substrate bonded to the sapphire substrate such that the plurality of epitaxy layers are disposed between the another substrate and the first roughened surface of the sapphire substrate, and wherein the another substrate includes at least two conductive terminals connected to opposite contacts of the light emitting diode.

2. The LED structure of claim 1 wherein sidewalls of the sapphire substrate are substantially free of laser charred marks.

3. The LED structure of claim 1 wherein the thickness of the sapphire substrate is about 250 μm to about 600 μm.

4. The LED structure of claim 1 wherein the another substrate includes silicon.

5. The LED structure of claim 1 wherein the second roughened surface includes a plurality of randomly distributed nano-sized dips.

6. The LED structure of claim 5 wherein the randomly distributed nano-sized dips have an average dimension of about 1 nanometer to about 10,000 nanometers.

7. The LED structure of claim 5 wherein the randomly distributed nano-sized dips have an average width of about 100 nanometers and about 10,000 nanometers.

8. The LED structure of claim 5 wherein an average distance between the randomly distributed nano-sized dips is about 200 nanometers to about 50,000 nanometers.

9. The LED structure of claim 5 wherein a depth of the randomly distributed nano-sized dips is less than or equal to about 4 microns.

10. A light emitting diode (LED) structure, comprising:
a baseboard; and
an LED device faced-down and electrically coupled to the baseboard, wherein the LED device includes:
a sapphire substrate having a thickness greater than or equal to about 250 μm, wherein the sapphire substrate includes a first roughened surface and a second roughened surface, the second roughened surface being opposite the first roughened surface, and further wherein the sapphire substrate includes sidewalls that extend between the first roughened surface and the second roughened surface that are substantially free of laser charring, and
an epitaxial structure disposed over the first roughened surface of the sapphire substrate, wherein the epitaxial structure is disposed between the baseboard and the first roughened surface.

11. The LED structure of claim 10 wherein the baseboard is a silicon substrate.

12. The LED structure of claim 10 wherein the second roughened surface includes a plurality of randomly distributed nano-sized dips.

13. The LED structure of claim 12 wherein the randomly distributed nano-sized dips include peaks and valleys, the valleys being substantially non-symmetrical.

14. The LED structure of claim 12 wherein the randomly distributed nano-sized dips include facets that follow a crystal orientation of the sapphire substrate.

15. A method comprising:
forming an epitaxial structure over a first roughened surface of a first substrate, wherein the epitaxial structure is configured as a light emitting diode (LED);
forming a roughened second surface of the first substrate, wherein the roughened second surface is opposite the first roughened surface;
bonding the first substrate to a second substrate, such that the epitaxial structure is disposed between the first roughened surface of the first substrate and the second substrate; and
singulating the first substrate and the second substrate to form LED dies, wherein the singulating the first substrate includes using a stealth dicing technique.

16. The method of claim 15 wherein no thinning process is performed on the first substrate.

17. The method of claim 15 wherein the forming the roughened second surface of the first substrate includes:
forming a patterned metal layer over a second surface of the first substrate that is opposite the first roughened surface, wherein the patterned metal layer has openings therein that expose the first substrate;
performing a dry etching process to remove portions of the exposed first substrate, thereby forming the roughened second surface of the first substrate, wherein the dry etching process uses the patterned metal layer as an etching mask.

18. The method of claim 17 wherein the forming the patterned metal layer over the second surface of the first substrate includes forming one of a patterned nickel layer and a patterned chromium layer.

19. The method of claim 15 wherein the forming the roughened second surface of the first substrate includes performing a lapping process using a nano-particle slurry on a second surface of the first substrate that is opposite the first roughened surface, thereby forming the roughened second surface of the substrate.

20. The method of claim 15 wherein the forming the roughened second surface of the first substrate includes:
forming a patterned hard mask layer over a second surface of the first substrate, the second surface being opposite the first roughed surface, wherein the patterned hard mask layer has openings therein that expose the first substrate;
performing a wet etching process to remove portions of the exposed first substrate, thereby forming the roughened second surface of the first substrate, wherein the wet etching process uses the patterned hard mask layer as an etching mask.
